(19) United States
(12) Patent Application Publication
(10) Pub. No.: US 2019/0094310 A1
(43) Pub. Date: Mar. 28, 2019

(54) ELECTRICAL ENERGY STORAGE SYSTEM

(71) Applicant: Siemens Aktiengesellschaft, Muenchen (DE)

(72) Inventor: Johannes REINSCHKE, Nuernberg (DE)

(73) Assignee: Siemens Aktiengesellschaft, Muenchen (DE)

(21) Appl. No.: 16/082,989

(22) PCT Filed: Dec. 7, 2016
(86) PCT No.: PCT/EP2016/080079

§ 371 Date: Sep. 7, 2018

(30) Foreign Application Priority Data
Mar. 8, 2016 (DE) 10 2016 203 730.7

(51) Int. Cl. G01R 31/3828; H01M 10/44; G01R 31/371; G01R 31/387; H02J 7/00

(52) U.S. Cl. CPC G01R 31/3828; H01M 10/44; H01M 2010/4271; G01R 31/387; H02J 7/007; G01R 31/371

(57) ABSTRACT

An electrical energy storage system includes at least one battery having a battery management system. In an embodiment, the electrical energy storage system includes a monitoring system which can identify critical states of the battery independently of the state of the battery management system.

### PRIORITY STATEMENT

This application is the national phase under 35 U.S.C. § 371 of PCT International Application No. PCT/EP2016/080079 which has an International filing date of Dec. 7, 2016, which designated the United States of America and which claims priority to German patent application number 102016203730.7 filed Mar. 8, 2016, the entire contents of which are hereby incorporated herein by reference.

### FIELD

An embodiment of invention generally relates to an electrical energy storage system.

### BACKGROUND

In electrical energy storage systems, there are critical states which, if they persist, can result in serious damage to the electrical energy storage system. For example, such a critical state is the deep discharge of the batteries in an electrical energy storage system and this is problematic, in particular, in lithium ion batteries. Furthermore, a low state of charge (SOC) or a poor state of health (SOH) of a battery may result in irreparable damage to the battery cells if no countermeasures are taken.

### SUMMARY

An embodiment of the invention discloses an electrical energy storage system which reliably detects a critical state for all conceivable battery and electrical energy storage system operating modes. After a critical state has been detected, either maintenance is requested by means of a remote message, which requests a person responsible for the installation to initiate countermeasures, or a measure suitable for eliminating the critical state is automatically started.

An embodiment of the invention is therefore based on providing a novel electrical energy storage system which independently detects critical states.

At least one embodiment of the invention is directed to an electrical energy storage system. Advantageous configurations of the electrical energy storage system are stated in the claims.

The electrical energy storage system according to at least one embodiment of the invention comprises at least one battery with a battery management system and a monitoring system which can detect critical states of the battery independently of the state of the battery management system.

The electrical energy storage system according to at least one embodiment of the invention comprises at least one battery with a battery management system and a monitoring system which can detect critical states of the battery independently of the state of the battery management system.

In this case, it is advantageous that the monitoring system detects critical states in an electrical energy storage system, for example the deep discharge or the state of health of the battery, converter temperatures which could result in a reduction in the service life of the converter, or overcurrents and overvoltages. As a result of the fact that the monitoring system can detect critical states of the battery independently of the state of the battery management system, the battery can be monitored, in particular, even when the battery management system is switched off. A battery management system which is switched off can generally be caused by a fault in the battery management system or in the battery. However, the battery management system may also have been actively switched off in order to minimize the self-discharge of the battery.

In one configuration embodiment, the monitoring system reports critical states. The critical states can be reported to an SMS telecontrol and reporting system.

In another configuration embodiment, the monitoring system comprises a computing unit with a model. The model in this computing unit may comprise a “black box” or “grey box” model, for example.

In another configuration embodiment, the model in the computing unit comprises, as parameters, the battery operating mode and further battery parameters.

In another configuration embodiment, the model in the computing unit of the monitoring system comprises battery operating mode parameters which are transmitted by a converter control and regulation system.

In another configuration embodiment, the model in the computing unit of the monitoring system comprises battery operating mode parameters which are transmitted by the battery management system.

### BRIEF DESCRIPTION OF THE DRAWINGS

The properties, features and advantages of this invention which are described above and the manner in which they are achieved become clearer and more distinctly comprehensible in connection with the following description of the exemplary embodiments which are explained in more detail in connection with the figures, in which:

FIG. 1 shows a conventional electrical energy storage system;

FIG. 2 shows an electrical energy storage system of an example embodiment having a battery and a monitoring system;

FIG. 3 shows an electrical energy storage system of an example embodiment having a battery, a battery management system and a monitoring system; and

FIG. 4 shows an alternative electrical energy storage system of an example embodiment having a battery, a battery management system and a monitoring system.

### DETAILED DESCRIPTION OF THE EXAMPLE EMBODIMENTS

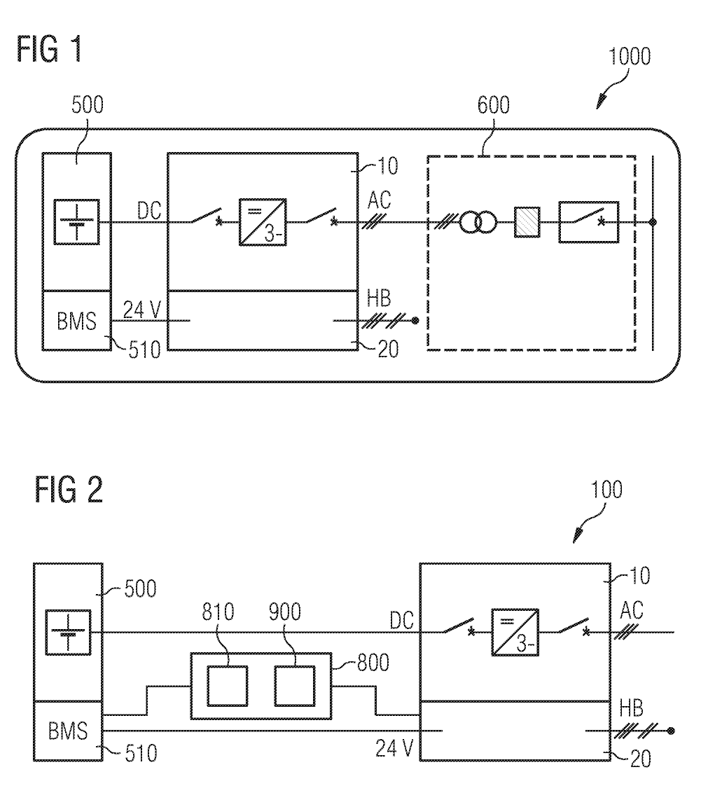

FIG. 1 illustrates a conventional electrical energy storage system 1000. This system comprises a battery 500 with a battery management system 510, a converter 10 with a converter control and regulation system 20, and a network supply 600. The network supply 600 is used, for example, to supply a medium-voltage network.

FIG. 2 illustrates the electrical energy storage system 100 according to an embodiment of the invention. This system comprises the battery 500 with the battery management system 510 and a monitoring system 800. The monitoring system 800 is connected to the converter control and regulation system 20 using communication technology and is optionally also connected to the battery management system 510. This monitoring system 800 detects critical states of the battery 500 independently of the state of the battery management system 510.

The monitoring system 800 may likewise report these critical states of the battery 500. An SMS telecontrol and reporting system 900 may be provided for this purpose and requests a person responsible for the installation to initiate countermeasures. This can take place using an SMS (“Short Message Service”), for example.

In addition to the battery operating modes of “charging” and “discharging”, there are also other operating modes such as “self-supply” or “energy-saving”. In the “self-supply” operating mode, the auxiliary energy needed to operate the battery management system 510 is not taken from an external auxiliary voltage supply, but rather from the battery 500 itself. In the “energy-saving” battery mode, the battery 500 is put to sleep, that is to say the battery management system 510 is powered down to a minimum function or is completely switched off. In the “energy-saving” battery mode, the battery management system 510 generally no longer communicates with the outside. In particular, in the energy-saving mode, it is no longer possible to query the state of charge or any other state of the battery 500.

According to FIG. 2, a computing unit with a model 810, which models the battery state dynamically (on the basis of time), is therefore provided in the monitoring system 800. Inside the monitoring system 800, it is the computing unit 810 which is connected to the converter control and regulation system 200 using communication technology and optionally also to the battery management system 510. The model in the computing unit 810 may be a “black box” or “grey box” model which continuously calculates battery parameters, for example SOC and/or SOH values of the battery. The model output parameters are adapted to the measured values of the SOC and/or SOH, for example, communicated by the battery management system 510 as soon as new SOC or SOH measured values are available.

Multi-dimensional, piecewise affine linear interpolation models, multi-dimensional spline models or neural networks (for example with radial basis functions) are preferably used as “black box” models. In contrast to “black box” models, “grey box” models contain physical relationships or partial models which are supplemented with empirical partial models.

Standard system identification methods, for example from Ljung: System Identification: Theory for the User (2nd Edition) or from Michel Verhaegen: Filtering and System Identification: A Least Squares Approach, are used for the initial off-line adaptation of the model parameters and for the online adaptation of the model parameters.

The computing unit 810 with the dynamic model calculates the output variables of the model on the basis of parameters which are known to the monitoring system 800 as a result of its connection using communication technology. These may be, for example, charging or discharging currents, current change rates, short-term current fluctuations or battery ambient temperatures. Provision may also be made for the dynamic model 810 to use battery operating mode parameters which are communicated by the battery management system 510, for example the battery temperature. A model which does not use any dependence on the battery operating mode parameters communicated by the battery management system 510 is preferably used.

The monitoring system 800 is preferably connected to at least one analog or digital input of an SMS telecontrol and reporting system 900. If the model 810 in the monitoring system 800 detects a critical battery state, the monitoring system 800 activates the analog or digital input of the connected telecontrol and reporting system 900. The reporting system 900 is configured in such a manner that, if the input is activated, an SMS is sent to the installation or building control room responsible for monitoring the operation of the electrical storage system 100.

If the reporting system 900 has at least one analog or digital output which is connected to the monitoring system 800 of the electrical energy storage system 100, an action frequency which increases the state of charge or the state of health is triggered in the monitoring system 800 in the event of a low state of charge and/or battery state of health. If it is possible to charge the battery 500 in the existing battery operating mode, the battery 500 is charged. If it is not possible to charge the battery 500 in the existing battery operating mode, the operating mode is first of all changed and a charging operation is then started.

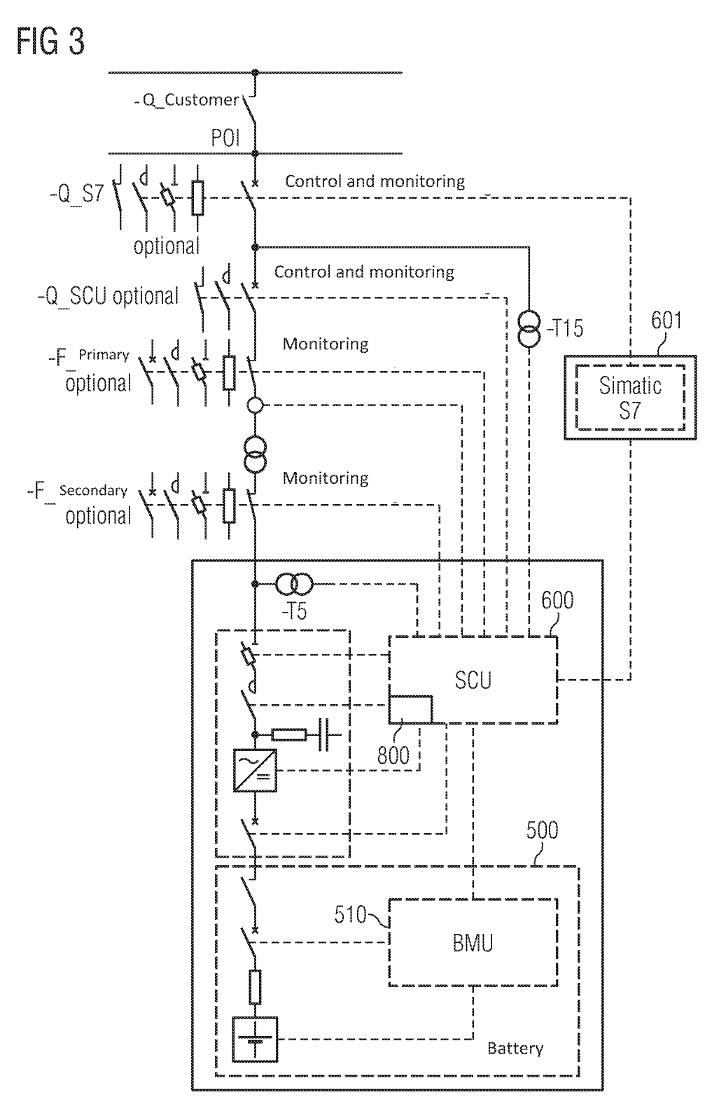

FIG. 3 again illustrates a battery 500 with a battery management system 510. A real-time regulation system (storage control unit, SCU) 600 is also indicated and regulates the converter(s) 10 in real time. For example, this real-time regulation system 600 can query or calculate measured values or parameters within 200 μs. The monitoring system 800 may be part of the real-time regulation system 600. The real-time regulation system 600 is part of the converter control and regulation system 20.

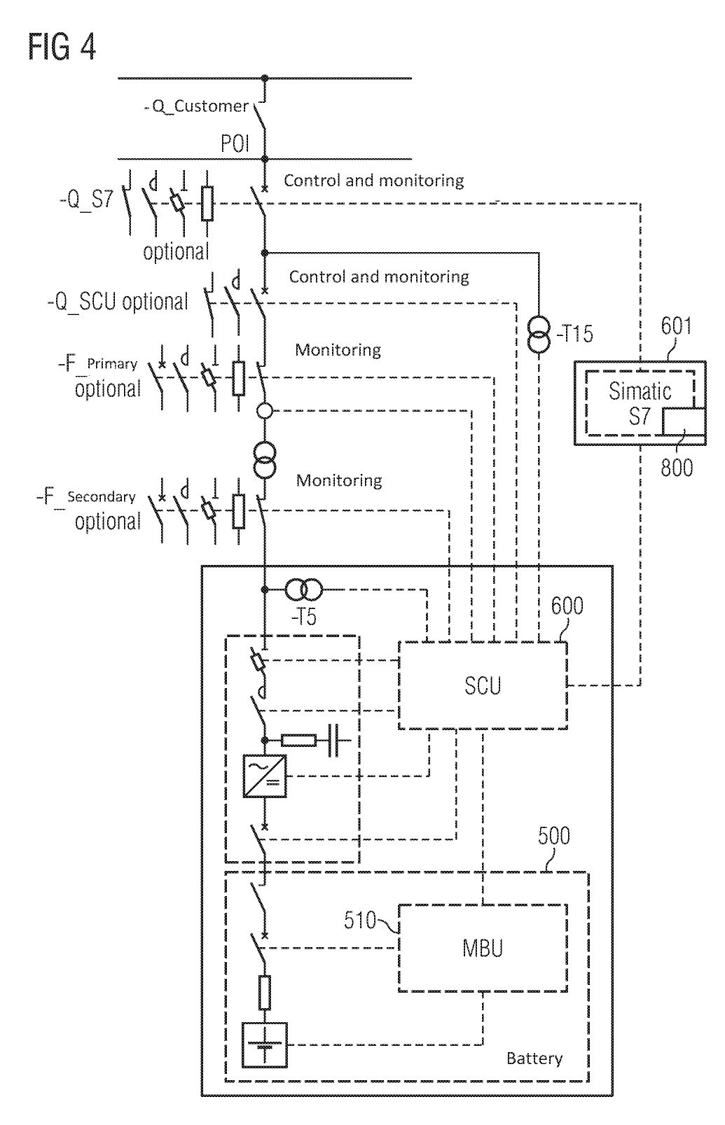

FIG. 4 also illustrates that the monitoring system 800 may be part of a control system 601. In this case, the control system 601, together with the real-time regulation system 600, forms the converter control and regulation system 20.

The electrical energy storage system 100 according to an embodiment of the invention therefore comprises a monitoring system 800 which comprises a state model. This state model models, in particular, the state of charge and the state of health of the battery 500, particularly in those situations in which the battery management system 510 is deactivated. The battery management system 510 is deactivated, for example, in the energy-saving mode of the battery 500.

1. An electrical energy storage system comprising:
at least one battery including a battery management system; and
a monitoring system to detect critical states of the battery independently of the state of the battery management system.

2. The electrical energy storage system of claim 1, wherein the monitoring system is configured to reports critical states.

3. The electrical energy storage system of claim 1, wherein the monitoring system is configured to report critical states to an SMS telecontrol and reporting system.

4. The electrical energy storage system of claim 1, further comprising a computing unit including a model.

5. The electrical energy storage system of claim 4, wherein the model included in the computing unit of the monitoring system includes a “black box” or “grey box” model.

6. The electrical energy storage system of claim 4, wherein the model included in the computing unit of the monitoring system includes parameters including at least of:
a battery operating mode; and
battery operating mode parameters.

7. The electrical energy storage system of claim 4, wherein the model included in the monitoring system includes parameters including:
battery operating mode parameters, transmittable by a converter control and regulation system.

8. The electrical energy storage system of claim 4, wherein the model included in the computing unit of the monitoring system includes parameters including:
battery operating mode parameters, transmittable by the battery management system.

9. The electrical energy storage system of claim 2, wherein the monitoring system is configured to report the critical states to an SMS telecontrol and reporting system.

10. The electrical energy storage system of claim 2, further comprising a computing unit including a model.

11. The electrical energy storage system of claim 10, wherein the model included in the computing unit of the monitoring system includes a “black box” or “grey box” model.

12. The electrical energy storage system of claim 5, wherein the model included in the computing unit of the monitoring system includes parameters including at least of:
a battery operating mode; and
battery operating mode parameters.

13. The electrical energy storage system of claim 10, wherein the model included in the computing unit of the monitoring system includes parameters including at least of:
a battery operating mode; and
battery operating mode parameters.

14. The electrical energy storage system of claim 11, wherein the model included in the computing unit of the monitoring system includes parameters including at least of:
a battery operating mode; and
battery operating mode parameters.

15. The electrical energy storage system of claim 5, wherein the model included in the monitoring system includes parameters including:
battery operating mode parameters, transmittable by a converter control and regulation system.

16. The electrical energy storage system of claim 5, wherein the model included in the computing unit of the monitoring system includes parameters including:
battery operating mode parameters, transmittable by the battery management system.

17. The electrical energy storage system of claim 5, wherein the model included in the monitoring system includes parameters including:
battery operating mode parameters, transmittable by a converter control and regulation system.

18. The electrical energy storage system of claim 5, wherein the model included in the computing unit of the monitoring system includes parameters including:
battery operating mode parameters, transmittable by the battery management system.
